(19) United States
(12) Patent Application Publication
(10) Pub. No.: US 2025/0279267 A1
(43) Pub. Date: Sep. 4, 2025

(54) SEMICONDUCTOR PROCESSING SYSTEM

(71) Applicant: Samsung Electronics Co., Ltd., Suwon-si (KR)

(72) Inventors: Hyeonjun Yun, Suwon-si (KR); Byungyong Choi, Suwon-si (KR); Yunha Kim, Suwon-si (KR); Jonghyun Kim, Suwon-si (KR); Minsun Ryu, Suwon-si (KR); Sangsu Yeh, Suwon-si (KR); Jingun U, Suwon-si (KR); Seungwoo Cha, Suwon-si (KR); Jongik Hong, Suwon-si (KR)

(21) Appl. No.: 18/991,803

(22) Filed: Dec. 23, 2024

(30) Foreign Application Priority Data
Mar. 4, 2024 (KR) 10-2024-0030691

(51) Int. Cl. H01J 37/32

(52) U.S. Cl. CPC H01J 37/32972; H01J 37/32926; H01J 37/3299; H01J 2237/3341

(57) ABSTRACT

A semiconductor processing system includes a plurality of chambers respectively having a space in which a semiconductor process using plasma is undertaken, a view port in the chamber body, an optical cable unit including a rotating body and a plurality of optical cables, a first end of each cable being connected to the view port and a second end to the rotating body, a plurality of Optical Emission Spectroscopy (OES) apparatuses detecting light emitted from the plasma and generating OES data, and a processor. The plurality of OES apparatuses generate OES data whenever the rotating body rotates and an area in contact with the rotating body changes. The processor corrects the OES data and calculates a process representing variable (PRV), and operates the plurality of chambers according to a semiconductor process condition calculated using the PRV. Thereby, reliability of the semiconductor processing system may be improved.

### CROSS-REFERENCE TO RELATED APPLICATION(S)

This application claims the benefit under 35 USC 119(a) of Korean Patent Application No. 10-2024-0030691 filed on Mar. 4, 2024 in the Korean Intellectual Property Office, the entire disclosure of which is incorporated herein by reference for all purposes.

### BACKGROUND

The present inventive concept relates to a semiconductor processing system.

Semiconductor processes such as deposition and etching using plasma may be performed in semiconductor processing apparatuses. In an etching process using plasma, end point detection (EPD), virtual metrology (VM), chamber abnormality detection, or the like, may be important. Optical Emission Spectroscopy (OES) is widely used to monitor a plasma state in the chamber. However, data generated by OES equipment performing optical emission analysis may have deviations due to semiconductor processing apparatuses and/or OES equipment. Therefore, controlling the semiconductor process based only on data generated by OES equipment may have low accuracy.

### SUMMARY

Example embodiments provide a semiconductor processing system in which an OES apparatus generates OES data for all combinations of chambers and OES apparatuses, and deviations present in OES data are corrected to calculate a process representing variable (PRV) that may be matched to the semiconductor process results, thereby controlling a semiconductor process by monitoring the PRV while the semiconductor process is in progress.

According to example embodiments, a semiconductor processing system includes a plurality of chambers, each chamber including a chamber body having a space in which a semiconductor process using plasma is undertaken, and a view port installed in the chamber body, an optical cable unit including a rotating body and a plurality of optical cables, a first end of each of the plurality of optical cables being connected to a corresponding view port and a second end being connected to the rotating body, a plurality of Optical Emission Spectroscopy (OES) apparatuses configured to detect light emitted from plasma of a corresponding chamber and generate OES data, and at least one processor configured to control the plurality of chambers, the optical cable unit, and the plurality of OES apparatuses. The plurality of OES apparatuses are configured to generate the OES data at different orientations of the rotating body. The at least one processor is configured to correct the OES data to generate corrected OES data, to calculate a process representing variable (PRV) using the corrected OES data, and to operate the plurality of chambers according to a semiconductor process condition calculated using the PRV.

According to example embodiments, a semiconductor processing system includes a plurality of chambers, each chamber including a chamber body having a space in which a semiconductor process using plasma is undertaken, and a view port installed in the chamber body, an optical cable unit including a rotating body and a plurality of optical cables, a first end of each of the plurality of optical cables being connected to the view port and a second end being connected to the rotating body, a plurality of Optical Emission Spectroscopy (OES) apparatuses configured to detect light emitted from plasma of a corresponding chamber and generate OES data, and at least one processor configured to control the plurality of chambers, the optical cable unit, and the plurality of OES apparatuses. One surface of each of the plurality of OES apparatuses is in optical communication with the rotating body. Each of the plurality of OES apparatuses is configured to receive light emitted from the plasma of the corresponding chamber through each of the optical cables connected to an area in contact with the rotating body, and generate the OES data at different orientations of the rotating body. For example, each of the plurality of OES apparatuses can be configured to generate the OES data when the rotating body rotates based on a first direction and a side of the rotating body in contact with one surface of each of the plurality of OES apparatuses changes.

According to example embodiments, a semiconductor processing system includes a plurality of chambers, each chamber including a chamber body having a space in which a semiconductor process using plasma is undertaken, and a view port installed in the chamber body, a measurement unit (e.g., a sensor) acquiring measurement data from a wafer that has been processed by the semiconductor process, an optical cable unit including a rotating body and a plurality of optical cables, a first end of each of the plurality of optical cables being connected to the view port and a second end being connected to the rotating body, a plurality of Optical Emission Spectroscopy (OES) apparatuses configured to detect light emitted from plasma of a corresponding chamber and generate OES data, a measurement unit (e.g., a sensor) acquiring measurement data from a wafer that has been processed by the semiconductor process, and at least one processor controlling the plurality of chambers, the optical cable unit, the plurality of OES apparatuses, and the measurement unit (e.g., sensor). The plurality of OES apparatuses can be configured to generate the OES data at different orientations of the rotating body. The plurality of OES apparatuses can be configured to measure intensity according to wavelength from an optical spectrum of light emitted from the plasma and generate the OES data including a plurality of peaks. The at least one processor can be configured to generate corrected OES data by correcting each of the plurality of peaks of at least one piece of the OES data for each of the plurality of chambers with a reference wavelength and reference intensity, creates a process model using a process representing variable calculated using the corrected OES data, and calculates a target process representing variable from the process model. The at least one processor can be configured to operate the plurality of chambers according to a semiconductor process condition for each of the plurality of chambers calculated using the process representing variable, the process model, and the target process representing variable.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a diagram illustrating a system according to example embodiments;

FIG. 2 is a diagram schematically illustrating a semiconductor processing system according to example embodiments;

FIG. 3 is a diagram schematically illustrating a semiconductor processing system according to example embodiments;

FIG. 4 is a diagram schematically illustrating a semiconductor processing system according to example embodiments;

FIG. 5 is a diagram schematically illustrating a semiconductor processing system according to example embodiments;

FIG. 6 is a flowchart illustrating an operation process of a semiconductor processing system according to example embodiments;

FIG. 7 is a flowchart illustrating the process of generating an OES data deviation model and calculating a process representing variable using OES data according to example embodiments;

FIG. 8 is a diagram illustrating OES data according to example embodiments;

FIG. 9 is a diagram illustrating an OES data deviation model according to example embodiments;

FIG. 10 is a diagram illustrating process representing variables and semiconductor process results during a test process according to example embodiments;

FIG. 11 is a diagram illustrating process representing variables and semiconductor process results in a semiconductor process according to example embodiments;

FIG. 12 is a diagram illustrating a process model according to example embodiments;

FIGS. 13A to 14C are diagrams illustrating semiconductor process results according to example embodiments;

FIG. 15 is a diagram illustrating a rotating body and a plurality of OES apparatuses according to example embodiments;

FIGS. 16 and 17 illustrate a cross-section in the direction I-I′ of FIG. 15 and are drawings illustrating the movement of a rotating body according to example embodiments;

FIGS. 18 and 19 are diagrams schematically illustrating a semiconductor processing system according to example embodiments; and

FIG. 20 is a flowchart illustrating a process of generating OES data during a test process performed before a semiconductor process is performed according to example embodiments.

### DETAILED DESCRIPTION

Hereinafter, example embodiments will be described with reference to the accompanying drawings.

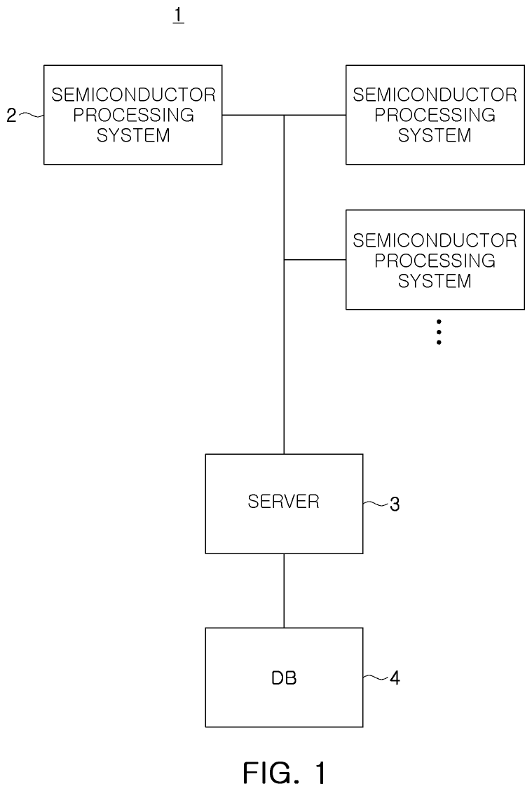

FIG. 1 is a diagram illustrating a system according to example embodiments.

Referring to FIG. 1, a system 1 may include at least one semiconductor processing system 2, a server 3, and a data base (DB) 4. The system 1 may monitor semiconductor process results and control the semiconductor process in real time through various diagnostic results monitoring the plasma, and which directly affect the semiconductor process results. For example, the system 1 according to example embodiments may diagnose and/or monitor the plasma using an Optical Emission Spectroscopy (OES) apparatus (e.g., an optical emission spectrometer).

In example embodiments, at least one semiconductor processing system 2 may include a plurality of chambers, an optical cable unit including a rotating body and a plurality of optical cables, a plurality of OES apparatuses, and a processor. Each of the plurality of chambers may include a chamber body having a space in which a semiconductor process using plasma is performed.

An optical cable may be composed of multiple optical fibers. Each fiber may totally reflect light incident on the fiber based on the difference in refractive index between the cladding and the core. An optical cable may emit light by diffusing or leaking light incident on the fiber, but may not be limited thereto.

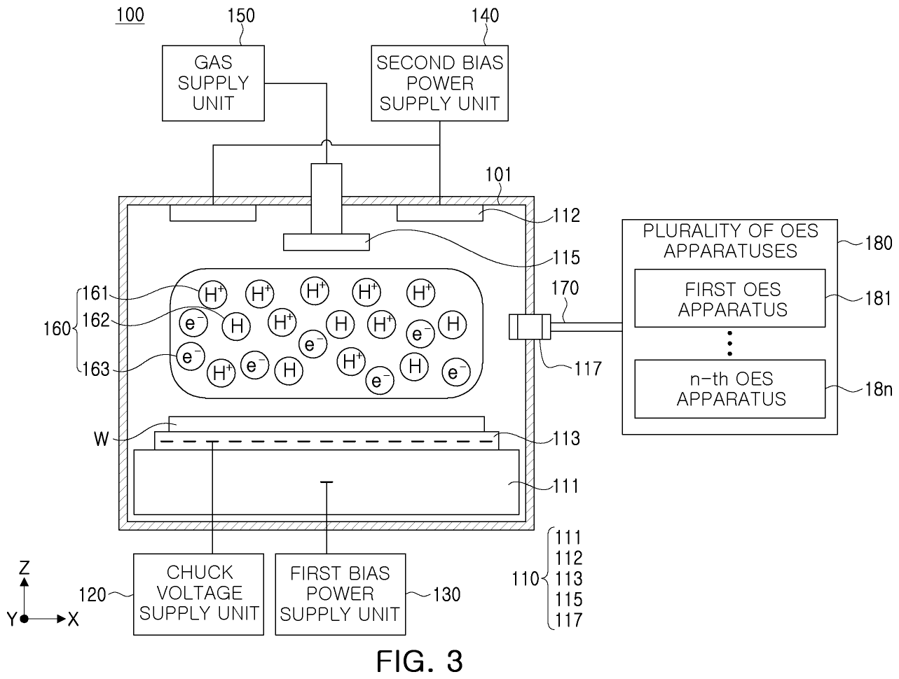

Each of the plurality of OES apparatuses may diagnose the plasma by receiving light emitted from the plasma through a plurality of optical cables. For example, a first end of each of the plurality of optical cables may be connected to a view port of the chamber, and the second end may be connected to the OES apparatus, as illustrated in the example of FIG. 3 below. A plurality of OES apparatuses may detect the optical spectrum of light emitted from the plasma, and may measure the intensity according to the wavelength of the light emitted from the plasma from the detected optical spectrum, so as to generate OES data. The processor may calculate one or more Process Representing Variable (PRV) based on the generated OES data.

Depending on the chamber in which the plasma is generated and the OES apparatus that detects light emitted by the plasma, there may be deviations in OES data. For example, depending on the performance variation of the chamber, there may be a variation in the intensity of the light (e.g., variation in the spectral density) emitted from the plasma as a function of the wavelength. Alternatively or additionally, depending on the OES apparatus, there may be deviations in the wavelengths of light emitted from the plasma.

Generally, in a semiconductor processing system, a view port and an OES apparatus connected to each of a plurality of optical cables may be fixed. For example, since one OES apparatus that detects light emitted from the plasma may be fixedly connected to one chamber, deviations may occur among OES data generated from a plurality of OES apparatuses connected to a plurality of chambers. Therefore, a process representing variable may be calculated using OES data with deviations, and the calculated plurality of process representing variables may fail to describe the semiconductor process results accurately.

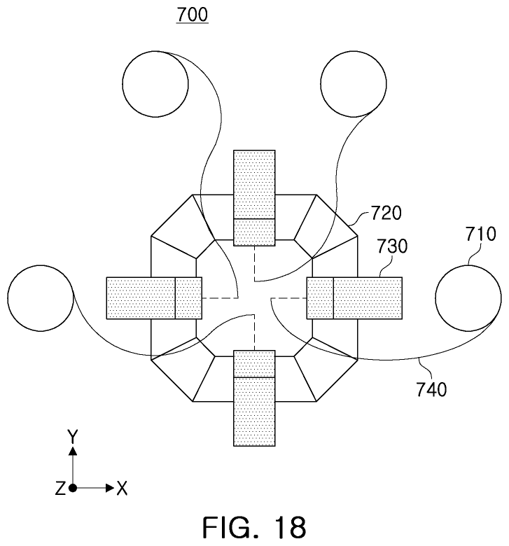

The semiconductor processing system 2 according to example embodiments may swap the OES apparatus in contact with the second end of each of the plurality of optical cables. For example, the semiconductor processing system 2 may use a rotating body mechanism in order to swap among the OES apparatuses, as illustrated in the examples of FIGS. 18-20 below, but is not limited thereto, and any means that performs the same function may be used. Accordingly, OES data may be generated for all combinations of multiple chambers and multiple OES apparatuses. The semiconductor processing system 2 may calculate the process representing variable after correcting the deviation of the OES data generated by swapping among the possible combinations of chambers and OES apparatuses, and the calculated single process representing variable may be accurately matched to the semiconductor process results.

For example, a semiconductor process performed in a respective chamber may correspond to a process of etching a mask layer and/or a mold layer on a wafer. In this example, the semiconductor process conditions calculated by the processor may include at least one of the internal temperature and pressure of the chamber, the time, temperature, flow rate of gas, pressure, and radio frequency (RF) of passivation for the photoresist, and the time and temperature of etching, gas flow, pressure, and RF for the photoresist.

In example embodiments, semiconductor process conditions for each of a plurality of chambers may be calculated using process representing variables calculated through a test process before proceeding with the semiconductor process. The semiconductor processing system 2 may perform a semiconductor process by operating semiconductor processing apparatuses according to the calculated semiconductor process conditions. Additionally, the semiconductor processing system 2 may calculate a process representing variable while the semiconductor process is in progress, and may modify the semiconductor process conditions for at least one chamber therethrough. Accordingly, the plurality of chambers may be controlled to produce uniform semiconductor process results.

According to example embodiments, data generated and calculated in the semiconductor processing system 2 may be transmitted to the server 3. For example, the data may include at least one of OES data, process representing variables, semiconductor process conditions, and process results. The server 3 may transmit data received from the semiconductor processing system 2 to the DB 4. The DB 4 may store information received from server 3 and may transmit information to server 3, for example in response to a request by server 3.

The system 1 according to example embodiments may improve the reliability and yield of the semiconductor process by controlling each chamber using process representing variables, so as to produce uniform semiconductor process results.

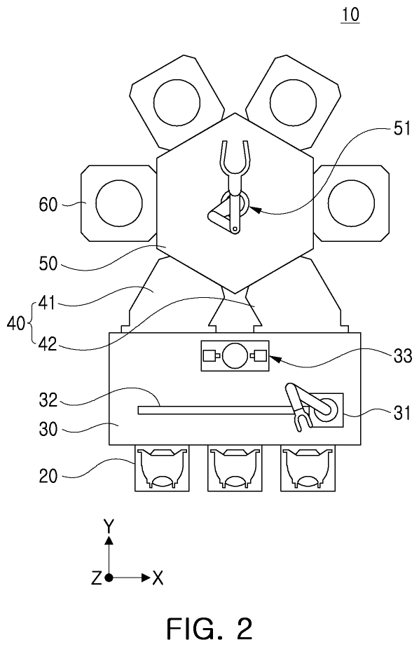

FIG. 2 is a diagram schematically illustrating a semiconductor processing system according to example embodiments.

Referring to FIG. 2, the semiconductor processing system 10 according to an example embodiment may include a wafer transfer device 30, a load lock chamber 40, a transfer chamber 50, a plurality of semiconductor processing apparatuses 60, and the like. For example, the wafer transfer device 30 may receive wafers through a container such as a Front Opening Unified Pod (FOUP) 20 inside the line where the semiconductor processing system 10 is installed. The wafer transfer device 30 may transfer the wafer received through the FOUP 20 to the load lock chamber 40, or may receive wafers in which semiconductor processing has been completed in semiconductor processing apparatuses 60, from the load lock chamber 40, to be stored in the FOUP 20.

The wafer transfer device 30 may include a wafer transfer robot 31 having an arm capable of holding a wafer, a rail unit 32 for moving the wafer transfer robot 31, an aligner 33 for aligning the wafer, and the like. Assuming an operation of transferring a wafer from the FOUP 20 to the load lock chamber 40, the wafer transfer robot 31 may take out the wafer stored in the FOUP 20 and place the wafer on the aligner 33. The aligner 33 may rotate the wafer to align the wafer in a predetermined direction. When wafer alignment is completed in the aligner 33, the wafer transfer robot 31 may take the wafer out of the aligner 33 and transfer the wafer to the load lock chamber 40.

The load lock chamber 40 is connected to the wafer transfer device 30, and may include a loading chamber 41 where wafers brought into the semiconductor processing apparatuses 60 to proceed with the semiconductor process temporarily reside, and an unloading chamber 42 where wafers that are transported out of the semiconductor processing apparatuses 60 upon completion of the process temporarily reside. When the wafer aligned in the aligner 33 is brought into the loading chamber 41, the inside of the loading chamber 41 is depressurized to prevent external contaminants from entering.

The load lock chamber 40 may be connected to the transfer chamber 50, and a plurality of semiconductor processing apparatuses 60 may be connected around the transfer chamber 50. A wafer transfer robot 51 may be placed inside the transfer chamber 50 to transfer wafers between the load lock chamber 40 and the plurality of semiconductor processing apparatuses 60. The wafer transfer robot 31 of the wafer transfer device 30 may be referred to as a first wafer transfer robot, and the wafer transfer robot 51 of the transfer chamber 50 may be referred to as a second wafer transfer robot.

Each of the plurality of semiconductor processing apparatuses 60 may perform a semiconductor process on a wafer. For example, a semiconductor process performed by a plurality of semiconductor processing apparatuses 60 may be/include a deposition process, an etching process, an exposure process, an annealing process, a polishing process, an ion implantation process, and the like.

To perform at least some of the above-mentioned semiconductor processes, plasma may be formed inside at least one of the plurality of semiconductor processing apparatuses 60. In an example, the plurality of semiconductor processing apparatuses 60 may each include a chamber body having a space in which a semiconductor process using plasma is performed, and a view port installed in the chamber body.

Plasma is formed on objects of semiconductor processing such as wafers, masks, and display mother substrates, and the results of semiconductor processing using plasma may be controlled according to the semiconductor processing conditions of the semiconductor processing apparatuses 60. Accordingly, by controlling the semiconductor processing conditions, the semiconductor processing apparatuses 60 may be controlled to produce uniform semiconductor processing results. Therefore, the yield of the semiconductor process may be improved.

The semiconductor processing system 10 according to example embodiments may further include an optical cable unit, a plurality of OES apparatuses, and a processor. The optical cable unit may include a rotating body and a plurality of optical cables, and a first end of each of the plurality of optical cables may be connected to a view port and the second end may be connected to the rotating body. The rotating body and OES apparatuses may be disposed inside or outside the transfer chamber 50, but may not be limited thereto.

A plurality of OES apparatuses may be in contact with a rotating body, and may generate OES data by receiving light emitted from the plasma through an optical cable connected to an area in contact with the rotating body. The plurality of OES apparatuses can be configured to generate the OES data at different orientations of the rotating body. For example, when the rotating body rotates and the areas in which the plurality of OES apparatuses contact the rotating body change, the plurality of OES apparatuses may generate the OES data. For example, OES data may be generated when the OES apparatus in contact with the second end of each of the plurality of optical cables is swapped. Accordingly, OES data may be generated for all combinations of the plurality of semiconductor processing apparatuses 60 and OES apparatuses.

In some examples, the processor may generate corrected OES data that corrects deviations in the OES data. Additionally, the processor may use the corrected OES data to calculate a process representing variable. For example, a process representing variable may be calculated for each of the plurality of semiconductor processing apparatuses 60, and the process representing variable may be matched with the semiconductor process results.

In example embodiments, semiconductor process conditions for each of the plurality of semiconductor processing apparatuses 60 may be calculated using process representing variables calculated through a test process before proceeding with the semiconductor process. The semiconductor processing system 10 may perform a semiconductor process by operating the semiconductor processing apparatuses 60 according to the calculated semiconductor process conditions. Additionally, the semiconductor processing system 10 may calculate a process representing variable while the semiconductor process is in progress, and may modify the semiconductor process conditions for at least one of the semiconductor processing apparatuses 60 through this. Accordingly, the semiconductor processing apparatuses 60 may be controlled to produce uniform semiconductor processing results.

Therefore, the reliability and yield of the semiconductor process may be improved by controlling each of the semiconductor processing apparatuses 60 to produce uniform semiconductor process results using the process representing variable.

FIG. 3 is a diagram schematically illustrating a semiconductor processing system according to example embodiments.

A semiconductor processing system 100 (e.g., a respective one of the at least one semiconductor processing system 2 of FIG. 1) may include a semiconductor processing apparatus, an optical cable 170, a plurality of OES apparatuses 180, and the like. Compared to FIG. 2, the semiconductor processing apparatus illustrated in FIG. 3 may correspond to one of the plurality of semiconductor processing apparatuses 60 in FIG. 2. The plurality of OES apparatuses 180 may include a first OES apparatus 181 to an nth OES apparatus 18n.

Referring to FIG. 3, a semiconductor processing apparatus according to an example embodiment may be equipment that performs a semiconductor process using plasma. The semiconductor processing apparatus may include a chamber 110, a chuck voltage supply unit 120, a first bias power supply unit 130, a second bias power supply unit 140, a gas supply unit 150, and the like.

The chamber 110 may include a chamber body 101, a first bias electrode 111, a second bias electrode 112, an electrostatic chuck (ESC) 113, a gas flow path 115, a view port 117, and the like. A process object to be processed by a semiconductor process may be seated on the electrostatic chuck 113. In an example embodiment illustrated in FIG. 3, the process object is illustrated as a wafer W (which may be an initial semiconductor substrate, such as a bulk silicon substrate) or an intermediate product formed by processing the initial substrate (e.g. the initial substrate with patterned layers formed thereon), but in various examples, the process object may instead be a display mother substrate, a mask, or the like.

For example, a plurality of protrusions having a protrusion shape may be formed on the upper surface of the electrostatic chuck 113. The wafer W is seated on the protrusion, and thus a space may be formed between the upper surface of the electrostatic chuck 113 and the wafer W. For example, the space between the upper surface of the electrostatic chuck 113 and the wafer W may be filled with helium gas or the like for cooling the wafer W.

In example embodiments, the wafer W may be fixed on the electrostatic chuck 113 by the Coulomb force generated from the chuck voltage supplied to the electrostatic chuck 113 by the chuck voltage supply unit 120. For example, the chuck voltage supply unit 120 may supply chuck voltage to the electrostatic chuck 113 in the form of constant voltage, and the chuck voltage may have a magnitude of hundreds to thousands of volts.

In an example embodiment different from that illustrated in FIG. 3, the wafer W may be seated on a vacuum chuck other than the electrostatic chuck 113, or may be fixed by a non-ESC-based support unit (non-chucking support unit). The non-ESC based support unit may fix the wafer W to the non-ESC based support unit using mechanical clamping, vacuum-based clamping or the like. However, the present inventive concept may not be limited thereto.

Plasma gas may flow in through the gas flow path 115 to conduct the semiconductor process. The first bias power supply unit 130 may supply first bias power to the first bias electrode 111 located below the electrostatic chuck 113, and the second bias power supply unit 140 may supply second bias power to the second bias electrode 112 located on the top of the electrostatic chuck 113. Each of the first bias power supply unit 130 and the second bias power supply unit 140 may include a radio frequency (RF) power source for supplying bias power. Depending on example embodiments, the bias electrode to which bias power is supplied may be installed only on the electrostatic chuck 113.

A plasma 160 including ions 161 and radicals 162 of the plasma gas, electrons 163, and the like may be generated in the chamber body 101 by the first bias power and the second bias power. For example, the plasma 160 may be generated in the space above the wafer W, and the reaction gas may be activated by the plasma 160 to increase reactivity. The plasma 160 may be used for one or more of the semiconductor processes performed by the plurality of semiconductor processing apparatuses 60, as described in the example of FIG. 2, such as an etching process, a deposition process, or the like.

A first end of the optical cable 170 may be connected to the view port 117. The second end of the optical cable 170 may contact one of the plurality of OES apparatuses 180. Light emitted from the plasma 160 may be transmitted to the OES apparatus adjacent to the second end of the optical cable 170 through the view port 117 and the optical cable 170. The OES apparatus may generate OES data by detecting light emitted from the plasma 160.

In example embodiments, the OES apparatus in optical communication with (e.g., in contact with or connected to) the second end of the optical cable 170 may be changed. For example, the OES apparatus in contact with the second end of the optical cable 170 may change from the first OES apparatus 181 to the second OES apparatus 182 and then to the third OES apparatus 183, but may not be limited thereto. Each OES apparatus in contact (e.g., in optical communication) with the optical cable 170 may generate its own set of OES data.

After each of the plurality of OES apparatuses 180 contacts the second end of the optical cable 170, corrected OES data that corrects the deviation between OES data may be generated. For example, the OES data may correspond to data detected by a plurality of OES apparatuses 180 of one semiconductor processing apparatus, and the deviation between the OES data may correspond to the deviation in the wavelength of light emitted from the plasma 160 between the plurality of OES apparatuses 180.

A process representing variable may be calculated using the corrected OES data, and a semiconductor process condition for a semiconductor processing apparatus may be calculated using the process representing variable. For example, during a testing process performed before the semiconductor process begins and/or while the semiconductor process such as etching or the like using the plasma 160 is performed, semiconductor process conditions may be calculated and/or modified using OES data. Semiconductor processing apparatuses may be operated according to semiconductor processing conditions.

In this manner, the process representing variable may be calculated by correcting the deviation of the OES data detected from the light emitted from the plasma 160, and semiconductor processing apparatuses may be controlled so that the calculated process representing variables are maintained in a normal range. For example, since the calculated process representing variable may be calibrated to the semiconductor process result, the semiconductor processing apparatus may be controlled to maintain the semiconductor process result in a normal range. For example, the semiconductor processing apparatuses may produce uniform semiconductor processing results (e.g., consistent with each other and/or reduced deviation from a targeted result), improving the yield and reliability of the semiconductor processing.

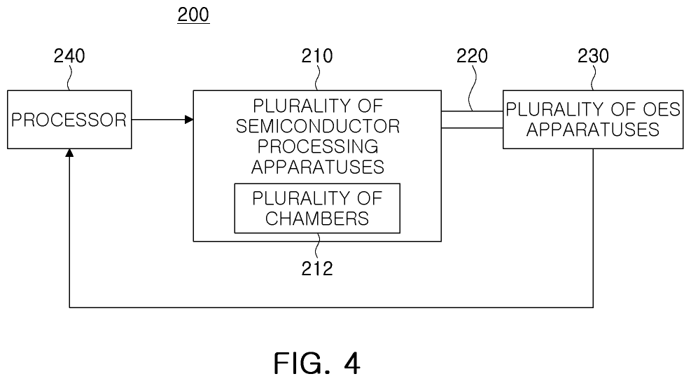

FIG. 4 is a diagram schematically illustrating a semiconductor processing system according to example embodiments.

Referring to FIG. 4, a semiconductor processing system 200 may include a plurality of semiconductor processing apparatuses 210, an optical cable unit 220, a plurality of OES apparatuses 230, a processor 240, and the like. The processor 240 may control a plurality of semiconductor processing apparatuses 210, an optical cable unit 220, and a plurality of OES apparatuses 230. Detailed embodiments of the semiconductor processing system 200 may be the same as those previously described in FIGS. 1 to 3. For example, the plurality of semiconductor processing apparatuses 210 may correspond to the semiconductor processing apparatus of FIG. 3, the optical cable unit 220 may correspond to the optical cable 170 of FIG. 3, and the plurality of OES apparatuses 230 may correspond to the plurality of OES apparatuses 180 of FIG. 3.

Each of the plurality of semiconductor processing apparatuses 210 may include a chamber. The plurality of chambers 212 included in the plurality of semiconductor processing apparatuses 210 may each include a chamber body having a space in which a semiconductor process using plasma is performed and a view port installed in the chamber body.

In example embodiments, the optical cable unit 220 may include a rotating body and optical cables. A first end of each optical cable may be connected to a view port. The second end of each optical cable may be in contact with a plurality of OES apparatuses 230. Light emitted from the plasma may be transmitted to each of the plurality of OES apparatuses 230 adjacent to the second end of the optical cable through the view port and the optical cable.

The processor 240 may swap the plurality of OES apparatuses 230 adjacent to the second end of the optical cable by rotating the rotating body. The plurality of OES apparatuses 230 may generate OES data each time the rotating body rotates. For example, at least one device among the plurality of OES apparatuses 230 that receives light emitted from the plasma may generate OES data by measuring the intensity according to the wavelength from the optical spectrum of the light emitted from the plasma.

Processor 240 may receive OES data from a plurality of OES apparatuses 230. Depending on the chamber in which plasma is generated and the OES apparatus that detects light emitted from the plasma, there may be deviations in OES data. The processor 240 may correct deviations in the OES data to generate corrected OES data, and calculate a process representing variable using the corrected OES data. For example, the process representing variable may be calculated for each of the plurality of semiconductor processing apparatuses 210.

Hereinafter, a process in which the semiconductor processing system 200 according to example embodiments performs a semiconductor process using OES data and process representing variables will be described in detail.

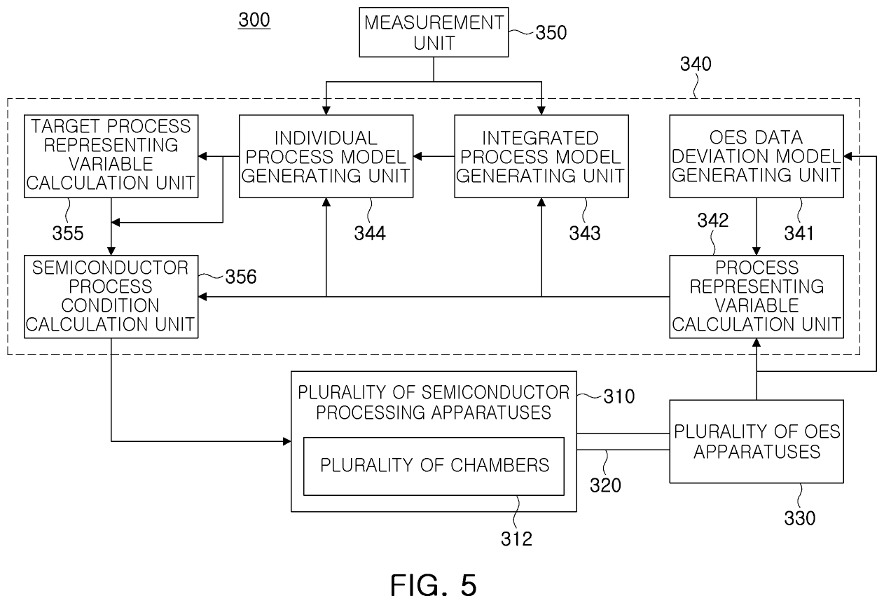

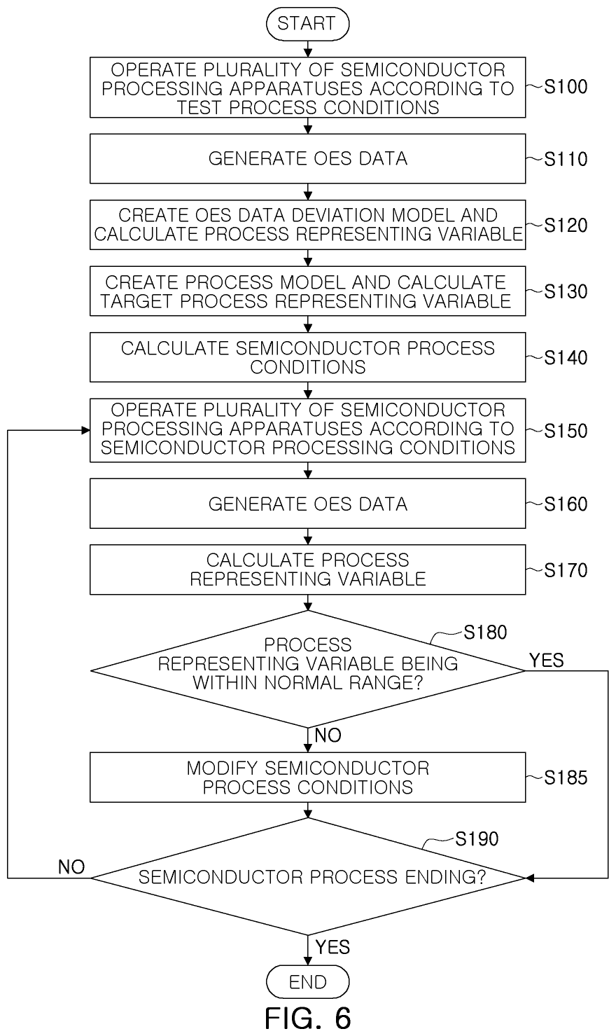

FIG. 5 is a diagram schematically illustrating a semiconductor processing system according to example embodiments. FIG. 6 is a flowchart illustrating the operation process of the semiconductor processing system according to example embodiments.

First, referring to FIG. 5, a semiconductor processing system 300 may include a plurality of semiconductor processing apparatuses 310, an optical cable unit 320, a plurality of OES apparatuses 330, a processor 340, and the like. The plurality of semiconductor processing apparatuses 310 may include a plurality of chambers 312 respectively including a chamber body and a view port installed in the chamber body. Detailed embodiments of the semiconductor processing system may be to the same as those previously described in FIGS. 1 to 4. For example, the plurality of semiconductor processing apparatuses 310 may correspond to the semiconductor processing apparatus of FIG. 3 and the plurality of OES apparatuses 330 may correspond to the plurality of OES apparatuses 180 of FIG. 3.

The optical cable unit 320 may include a rotating body and a plurality of optical cables. One end of each optical cable may be connected to a view port, and the other end of each optical cable may be connected to a rotating body. For example, the number of OES apparatuses 330 may be equal to the number of optical cables. The number of chambers 312 may be equal to the number of OES apparatuses 330.

The processor 340 may include an OES data deviation model generating module 341, a process representing variable calculation module 342, an integrated process model generating module 343, an individual process model generating module 344, a target process representing variable calculation module 355, a semiconductor process condition calculation module 356, and the like. For example, each of modules 341-356 may be in the form of a corresponding software module (e.g., a software routine) configuring the processor 340. Data generated and calculated by the processor 340 may be stored in DB 4 of FIG. 1. However, the present inventive concept may not be limited thereto.

Referring to FIGS. 5 and 6, the semiconductor processing system 300 may perform a test process before proceeding with the semiconductor process (S100 to S140). First, after a plurality of wafers are input into the plurality of semiconductor processing apparatuses 330, the plurality of semiconductor processing apparatuses 330 may be operated according to test process conditions (S100). In this example, the test process conditions may be the same for all of the plurality of semiconductor processing apparatuses 330. Plasma may be generated in each of the plurality of semiconductor processing apparatuses 330. For example, the plurality of wafers may include, but may not be limited to, 1000 wafers.

The plurality of OES apparatuses 330 may generate OES data by receiving light emitted from the plasma through an optical cable connected to an area in contact with the rotating body (S110). The plurality of OES apparatuses 330 can be configured to generate the OES data at different orientations of the rotating body. For example, when the rotating body rotates and the area in which the plurality of OES apparatuses 330 contact the rotating body changes, the plurality of OES apparatuses 330 may generate OES data.

The OES data may be a collection of data of all combinations of the plurality of chambers 312 and the plurality of OES apparatuses 330 for the plurality of wafers. For example, the OES data may include data on all combinations of the chamber in which the semiconductor process was performed and the plurality of OES apparatuses 330 for each wafer in which the semiconductor process was performed. For example, in a wafer on which a semiconductor process was performed in a first chamber, OES data may include data for each combination of the first chamber and a plurality of OES apparatuses.

For example, the plurality of OES apparatuses 330 may detect the optical spectrum of light emitted from the plasma, measure the intensity (e.g., the spectral density) as a function of the wavelength of the light emitted from the plasma from the detected optical spectrum, and generate OES data. The OES data may include multiple peaks.

Thereafter, the processor 340 may use the OES data to create an OES data deviation model and calculate a process representing variable (S120). For example, the OES data deviation model generating module 341 may generate an OES data deviation model using OES data. The process representing variable calculation module 342 may calculate the process representing variable using OES data and the OES data deviation model.

The OES data deviation model generating module 341 may generate an OES data deviation model using OES data. The OES data deviation model may include a wavelength deviation model and an intensity deviation model. The wavelength deviation model may correspond to the difference between the wavelength of a plurality of peaks of OES data and a reference wavelength, and the reference wavelength may be equal to the number of the plurality of peaks. The intensity deviation model may correspond to the difference between the intensity of a plurality of peaks in the OES data and the reference intensity, and the reference intensity may be equal to the number of the plurality of peaks.

The OES data deviation model may include OES data deviations for each combination of the plurality of chambers 312 and the plurality of OES apparatuses 330. In the case of having multiple OES data deviations for a combination of a single chamber and a single OES apparatus, the average of the multiple OES data deviations may correspond to the OES data deviation.

The process representing variable calculation module 342 may calculate the process representing variable using OES data and the OES data deviation model. For example, the process representing variable calculation module 342 may generate corrected OES data by applying the OES data deviation model to the OES data. For example, the corrected OES data may be obtained by correcting each of a plurality of peaks of the OES data with a reference wavelength and reference intensity. The plurality of peaks of the corrected OES data may include a first peak and a second peak, and the process representing variable may correspond to the first wavelength of the first peak divided by the second wavelength of the second peak. However, the present inventive concept may not be limited thereto.

The processor may create a process model and calculate the target process representing variable (S130). The process representing variable may be matched to the semiconductor process results, and the process model may include a trend line between the process representing variable and the semiconductor process results. A trend line may correspond to a linear function. The target process representing variable calculation module 355 may then calculate the target process representing variable by substituting the target semiconductor process results into the trend line. For example, semiconductor process results may include the pattern size (Critical Dimension (CD)).

The process model may include an integrated process model generated by the integrated process model generating module 343 and an individual process model generated by the individual process model generating module 344. The semiconductor processing system 300 may further include a measurement module 350 (e.g., a sensor). The measurement module 350 (e.g., sensor) may acquire measurement data from a wafer that has undergone a semiconductor process. The measurement module 350 (e.g., sensor) can include a scanning electron microscope (SEM) device, and the measurement data may include, but may not be limited to, the pattern size.

The integrated process model generating module 343 may create an integrated process model using process representing variables and measurement data. The integrated process model may include integrated trend lines between semiconductor process results versus process representing variables for a plurality of chambers.

The individual process model generating module 344 may generate an individual process model using process representing variables, measurement data, and an integrated process model. The individual process model generating module 344 may generate an individual process model by correcting the integrated process model to suit each of the plurality of chambers. The individual process model may include individual trend lines between semiconductor process results versus process representing variables for each of the plurality of chambers.

The semiconductor process condition calculation module 356 may calculate the semiconductor process conditions using the process representing variable, the individual process model, and the target process representing variable (S140). The semiconductor processing conditions may be for each of the plurality of semiconductor processing apparatuses 310. The semiconductor processing conditions may include, but are not limited to, at least one of the internal temperature and pressure of the plurality of chambers, the time and temperature of passivation for the photoresist, and the time and temperature of etching the photoresist.

After the test process is completed, the processor 340 may perform a semiconductor process (S150 to S190). For example, the processor 340 may operate a plurality of semiconductor processing apparatuses 310 according to semiconductor processing conditions (S150). A plurality of OES apparatuses 330 may generate OES data by receiving light emitted from the plasma through an optical cable connected to an area in contact with the rotating body (S160).

In an example, the rotating body of the optical cable unit may not rotate, differently from operation S110, and thus the area where the plurality of OES apparatuses 330 are in contact with the rotating body may not change. For example, unlike the OES data generated in operation S110, the OES data may be generated by a combination of a single chamber and a single OES apparatus for a single wafer. However, the present inventive concept may not be limited thereto.

The process representing variable calculation module 342 may calculate the process representing variable using OES data (S170). The process representing variable calculation module 342 may generate corrected OES data by correcting the OES data using an OES data deviation model for the single chamber and single OES apparatus in which the received OES data was generated. The process representing variable calculation module 342 may calculate a value obtained by dividing the first wavelength of the first peak of the corrected OES data by the second wavelength of the second peak as the process representing variable. A single wafer on which a semiconductor process is performed in a single chamber may be calculated as a single process representing variable.

The semiconductor process condition calculation module 356 may determine whether the process representing variable calculated by the process representing variable calculation module 342 is within the normal range (S180). The normal range may correspond to a certain range based on the target process representing variable. In the case of a process representing variable that does not fall within the normal range (NO in S180), the semiconductor process condition calculation module 356 may modify the semiconductor process conditions for the semiconductor processing apparatus corresponding to the process representing variable (S185). In the case of the process representing variables within the normal range (YES in S180), the semiconductor process conditions may not be modified.

Afterwards, if the semiconductor process has not ended (NO in S190), the processor 340 may continue to perform the semiconductor process (S150 to S190). When the semiconductor process is terminated (YES in S190), the processor 340 may terminate the semiconductor process.

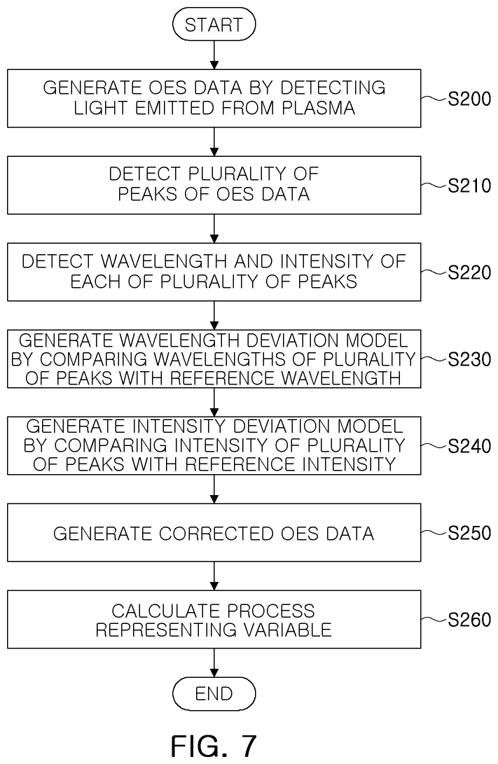

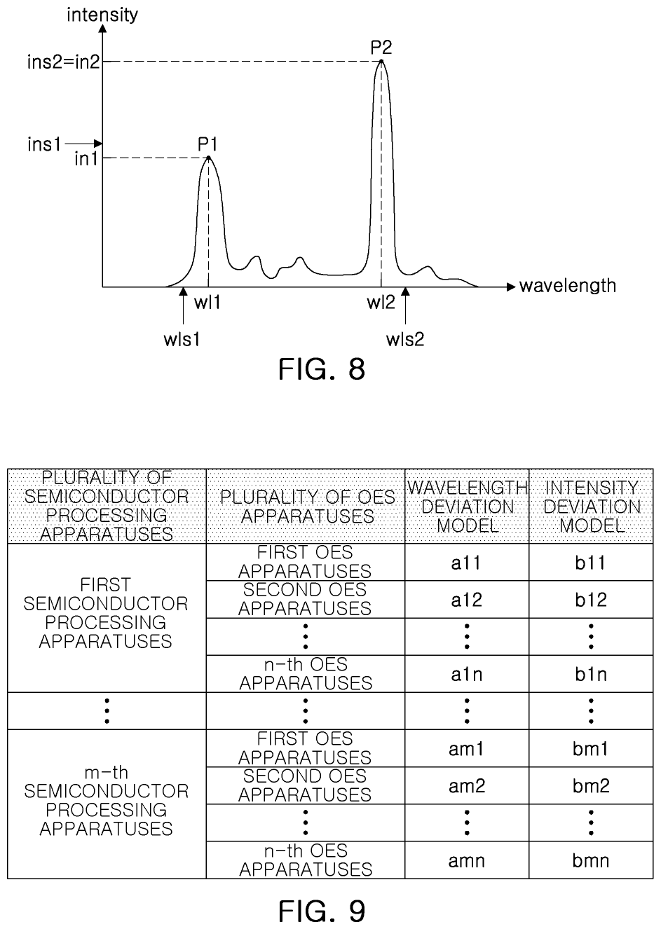

FIG. 7 is a flowchart illustrating the process of generating an OES data deviation model and calculating a process representing variable using OES data according to example embodiments. FIG. 8 is a diagram illustrating OES data according to example embodiments.

Detailed embodiments of the semiconductor processing system may be the same as those previously described in FIGS. 1 to 7. For example, as in FIG. 3, the semiconductor processing system may include a semiconductor processing apparatus, an optical cable, a plurality of OES apparatuses, and the like. The process illustrated in FIG. 7 may correspond to S110 to S130 in FIG. 6.

First, referring to FIG. 7, a plurality of OES apparatuses may generate OES data by detecting light emitted from the plasma (S200). For example, a plurality of OES apparatuses may detect the optical spectrum of light emitted from the plasma and measure the intensity according to the wavelength of the light emitted from the plasma from the detected optical spectrum to generate OES data. Additionally, as the rotating body rotates, OES data may be generated when the area in contact with the plurality of OES apparatuses and the rotating body changes.

FIG. 8 may illustrate OES data generated from a combination of a single chamber and a single OES apparatus for a single wafer, which may, as an example, correspond to OES data generated by a combination of the first chamber of the first semiconductor processing apparatus and the first OES apparatus. OES data may represent the intensity according to the wavelength of light emitted from the plasma. The unit of wavelength of light may be nm (nanometer), and the unit of intensity may be a.u. (arbitrary unit), but may not be limited thereto.

The processor may detect a plurality of peaks of the OES data (S210) and detect the wavelength and intensity of each of the plurality of peaks (S220). OES data may include a plurality of peaks, and the OES data illustrated in FIG. 8 may include a first peak P1 and a second peak P2. The first peak P1 may have a first intensity in1 at the first wavelength wl1, and the second peak P2 may have a second intensity in2 at the second wavelength wl2.

Next, referring to FIG. 7, the processor may generate an OES data deviation model (S230 and S240). The OES data deviation model generating module may generate an OES data deviation model, and the OES data deviation model may include a wavelength deviation model and an intensity deviation model. The OES data deviation model may include a wavelength deviation model and an intensity deviation model for each OES data generated in operation S200.

The OES data deviation model generating module may generate a wavelength deviation model by comparing the wavelengths of a plurality of peaks of the OES data and the reference wavelength (S230). The reference wavelength may be equal to the number of peaks. The reference wavelength illustrated in FIG. 8 may include a first reference wavelength wls1 that may be compared to the first wavelength wl1 of the first peak P1, and a second reference wavelength wls2 that may be compared to the second wavelength wl2 of the second peak P2. The wavelength deviation model may correspond to the difference between the wavelengths of a plurality of peaks based on a reference wavelength. Accordingly, in this example, the wavelength deviation of the first wavelength wl1 may be a negative number, and the wavelength deviation of the second wavelength wl2 may be a positive number. However, the present inventive concept may not be limited thereto.

The OES data deviation model generating module may generate an intensity deviation model by comparing the intensity of a plurality of peaks of the OES data with the reference intensity (S240). The reference intensity may be equal to the number of peaks. The reference intensity illustrated in FIG. 8 may include a first reference intensity ins1 that may be compared with the first intensity in1 of the first peak P1, and a second reference intensity ins2 comparable to the second intensity in2 of the second peak P2. The intensity deviation model may correspond to the difference between the intensities of a plurality of peaks based on the reference intensity. Accordingly, the intensity deviation of the first intensity in1 may be a positive number, and the intensity deviation of the second intensity in2 may be 0. However, the present inventive concept may not be limited thereto.

In example embodiments, the process representing variable calculation module may correct the OES data and generate corrected OES data (S250). The corrected OES data may be one in which the OES data deviation model is reflected in the OES data, and each of a plurality of peaks of the OES data is corrected to a reference wavelength and reference intensity. Referring to FIG. 8, the first peak P1 may be corrected with the first reference wavelength wls1 and the first reference intensity ins1, and the second peak P2 may be corrected with the second reference wavelength wls2 and the second reference intensity ins2. For example, the corrected OES data for each of a plurality of semiconductor processing apparatuses in which the same semiconductor process was performed may include the same first peak and second peak.

Thereafter, the process representing variable calculation module may calculate the process representing variable using the corrected OES data (S260). For a plurality of wafers that have undergone the same semiconductor process in a single semiconductor processing apparatus, a process representing variable for each of the plurality of wafers may be calculated. According to example embodiments, process representing variables may be matched with semiconductor process results. The process representing variable may be the first wavelength of the first peak of the corrected OES data divided by the second wavelength of the second peak. The process representing variable calculated from the OES data illustrated in FIG. 8 may be a value obtained by dividing the first reference wavelength wls1 by the second reference wavelength wls2. However, the present inventive concept may not be limited thereto.

FIG. 9 is a diagram illustrating an OES data deviation model according to example embodiments.

The OES data deviation model illustrated in FIG. 9 may correspond to the OES data deviation according to a combination of a plurality of semiconductor processing apparatuses and a plurality of OES apparatuses performing the same semiconductor process. Additionally, the OES data deviation model illustrated in FIG. 9 may correspond to the OES data deviation model for one of the plurality of peaks of the OES data.

The number (m) of the plurality of semiconductor processing apparatuses (1st to mth semiconductor processing apparatuses) may be the same as or different from the number (n) of the plurality of OES apparatuses (1st to nth OES apparatuses). A plurality of OES apparatuses may generate OES data each time the rotating body rotates. As the rotating body of the optical cable unit rotates, the areas in contact with the rotating body of the plurality of OES apparatuses change, and the plurality of OES apparatuses and the combination of the plurality of OES apparatuses may change.

The OES data deviation model may include a wavelength deviation model (a11-amn; a) and an intensity deviation model (b11-bmn; b). A wavelength deviation model (a) and an intensity deviation model (b) may be generated for each combination of a semiconductor processing apparatus and an OES apparatus. For example, when light emitted from the plasma generated in the first semiconductor processing apparatus is detected by the second OES apparatus, a 12th wavelength deviation a12 and a 12th intensity deviation b12 may be generated.

OES data may vary depending on the chamber and/or OES apparatus. For example, depending on the performance of the chamber, there may be a difference in the intensity of light emitted from the plasma depending on the wavelength. Depending on the OES apparatus, there may be deviations in the wavelength of light emitted from the plasma.

The OES data deviation model according to example embodiments may be used to correct deviations in OES data by the chamber and/or OES apparatus. Therefore, the process representing variable may be calculated using OES data from which deviations due to a combination of a semiconductor processing apparatus and an OES apparatus that have undergone the same semiconductor process have been removed. The process representing variables may be matched to semiconductor process results. For example, the semiconductor process may be controlled by monitoring process representing variables.

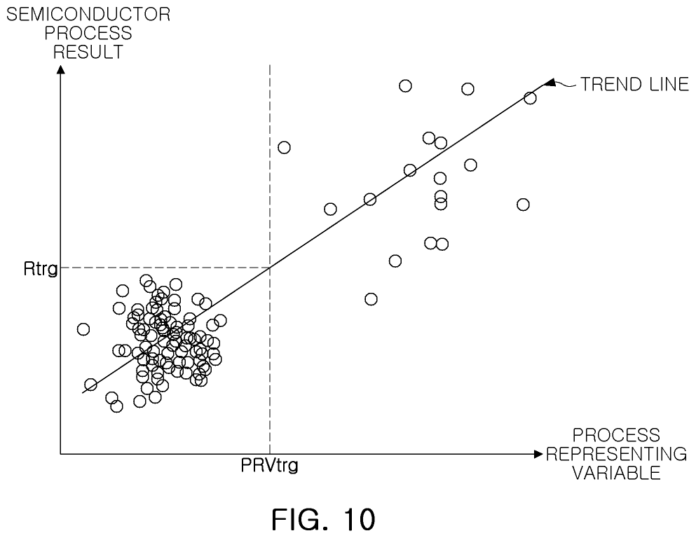

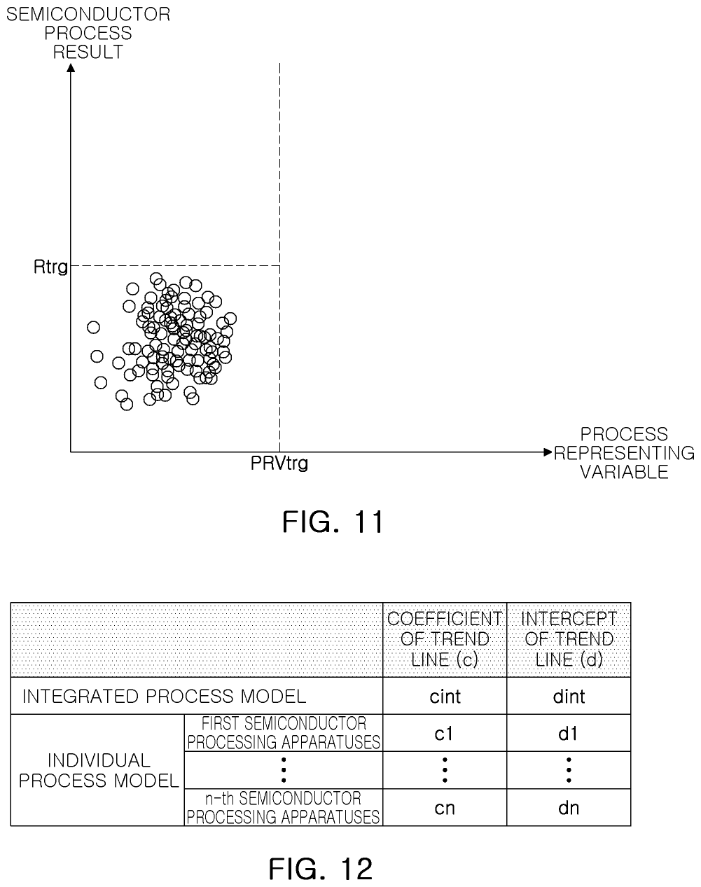

FIG. 10 is a diagram illustrating process representing variables and semiconductor process results during a test process according to example embodiments. FIG. 11 is a diagram illustrating process representing variables and semiconductor process results in a semiconductor process according to example embodiments. FIG. 12 is a diagram illustrating a process model according to example embodiments.

Detailed embodiments of the semiconductor processing system may be the same as those previously described in FIGS. 1 to 9.

FIGS. 10 and 11 may illustrate process representing variables and semiconductor process results matching thereto. The process representing variable may be calculated from light emitted from plasma generated in at least one semiconductor processing apparatus in which the same semiconductor process is in progress. In example embodiments, the ongoing semiconductor process corresponds to a process of etching a mask layer on a wafer, and the semiconductor process result may correspond to the pattern size. The unit of pattern size may be nm (nanometer), but may not be limited thereto.

FIG. 10 may illustrate semiconductor process results matching process representing variables calculated during a test process performed before proceeding with the semiconductor process. A process model may correspond to a trend line between semiconductor process results versus process representing variables. The trend line may correspond to a linear function (y=cx+d). The coefficient (c) and vertical intercept (d) of the extracted trend line may be included in the process model. However, the present inventive concept may not be limited thereto.

Process models may include integrated process models and individual process models. The individual process model may correspond to an integrated process model calibrated to suit each of a plurality of chambers, and the actual semiconductor process may proceed based on the individual process model.

In example embodiments, the process representing variable illustrated in FIG. 10 may be for a plurality of semiconductor processing apparatuses in which the same semiconductor process is performed. In this case, an integrated process model may be created, and the integrated process model may include an integrated trend line. Referring to FIG. 12, the integrated coefficient cint and integrated intercept dint may be extracted from the integrated trend line, and the integrated coefficient cint and the integrated intercept dint may be included in the integrated process model.

In another embodiment, the process representing variable illustrated in FIG. 10 may be for one semiconductor processing apparatus in which the same semiconductor process is performed. In this case, individual process models may be created, and individual process models may include individual trend lines. Referring to FIG. 12, individual coefficients c1 to cn and individual intercepts d1 to dn may be extracted from individual trend lines, and each pair of individual coefficients c1 to cn and individual intercepts d1 to dn may be included in an individual process model.

When the semiconductor processing apparatus on which the semiconductor process is performed is a first semiconductor processing apparatus, the first coefficient c1 and the first intercept d1 may be extracted from the individual trend line. The first coefficient c1 and the first intercept d1 may be included in an individual process model, and the individual process model may be applied only to the first semiconductor processing apparatus.

In addition, the target process representing variable PRVtrg may be calculated from the individual process model. Detailed embodiments of the target process representing variable PRVtrg may be the same as those previously described in FIGS. 5 and 6. A target semiconductor process result Rtrg may be set in advance for each semiconductor process. By substituting the target semiconductor process result Rtrg into the individual trend line, which is an individual process model, the target process representing variable PRVtrg may be calculated.

The semiconductor processing system according to example embodiments may control process conditions so that process representing variables are maintained in a normal range. The normal range may correspond to a certain range based on the target process variable PRVtrg. The maximum value of the normal range in an example embodiment illustrated in FIG. 11 may be the target process representing variable PRVtrg.

FIG. 11 may illustrate semiconductor process results matching process representing variables calculated while the same semiconductor process is in progress. Since the process representing variables all have smaller values than the target process representing variable PRVtrg, it can be seen that the process conditions have been controlled to remain in the normal range.

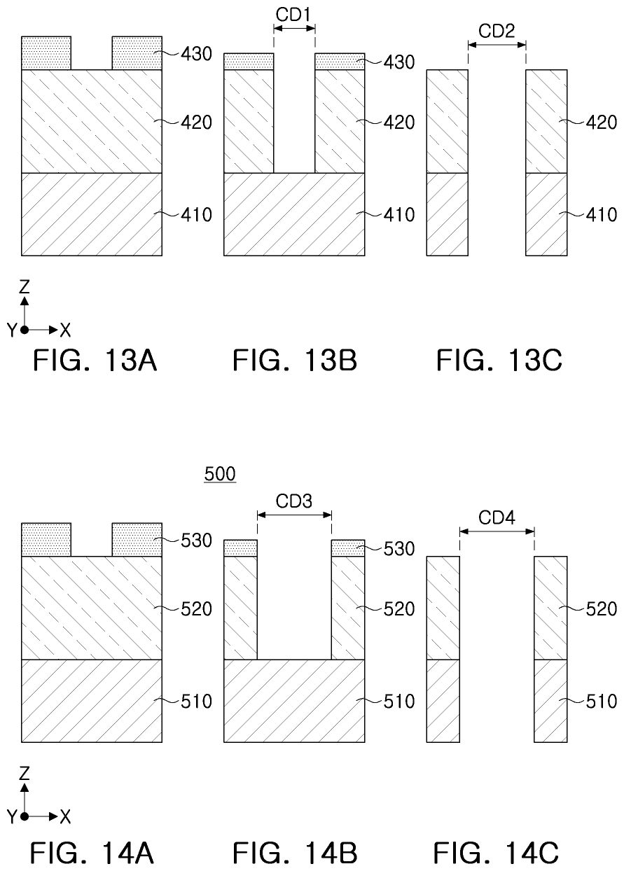

FIGS. 13A to 14C are diagrams illustrating the results of semiconductor processing according to example embodiments.

FIGS. 13A to 14C may illustrate semiconductor process results for first process objects 400 and 500 of the Example and Comparative Example, respectively. For a certain period of time, the semiconductor processing apparatus may be maintained in an idle state, with no wafers being input, and the standby state is maintained, and then the semiconductor process may proceed. The first process object may have lower semiconductor process results than the remaining process objects, due to the first wafer effect.

In the etching process object 400 according to example embodiments, the process conditions may be calculated through a test process before the semiconductor process is performed, and the semiconductor process results may be controlled by monitoring process representing variables while the semiconductor process is in progress. In the etching process object 500 of the example embodiment of the present inventive concept and other comparative examples, the semiconductor process proceeds according to predetermined process conditions, and the etching process result cannot be controlled while the semiconductor process is in progress.

Referring to FIG. 13A and FIG. 14A, the semiconductor process objects 400 and 500 may include mold layers 410 and 510 and mask layers 420 and 520 stacked along the Z axis of FIGS. 13 and 14, and the like. Photoresists 430 and 530 may be formed on the mask layers 420 and 520.

The hardness of the photoresist 430 in FIG. 13A may correspond to the target process result, but the hardness of the photoresist 530 in FIG. 14A may be lower than the target process result.

By monitoring process representing variables while passivation of the photoresist 430 in FIG. 13A is in progress, the time of passivation may be controlled so that the hardness of the photoresist 430 reaches the target hardness. Unlike this, the photoresist 530 of FIG. 14A undergoes passivation only for a preset time, and the time during which passivation proceeds cannot be controlled. Accordingly, the hardness of the photoresist 530 in FIG. 14A may be lower than the hardness of the photoresist 430 in FIG. 13A.

Referring to FIG. 13B and FIG. 14B, the results of the etching process for the mask layers 420 and 520 may be illustrated. The mask layer 420 in FIG. 13B may have a first pattern size CD1, and the mask layer 520 in FIG. 14B may have a third pattern size CD3. The first pattern size CD1 may correspond to the target process result, but the third pattern size CD3 may be larger than the first pattern size CD1. The difference in pattern size may be caused by a difference in hardness of the photoresists 430 and 530.

Referring to FIG. 13C and FIG. 14C, the results of the etching process for the mold layers 410 and 510 may be illustrated. The mold layer 410 in FIG. 13C may have a second pattern size CD2, and the mold layer 510 in FIG. 14C may have a fourth pattern size CD4.

The second pattern size CD2 may correspond to the target process result, but the fourth pattern size CD4 may be larger than the second pattern size CD2. Differences in the pattern sizes may also occur due to differences in hardness of the photoresists 430 and 530. For example, the difference in hardness of the photoresists 430 and 530 may also affect the subsequent etching process.

Therefore, as in the example embodiment of the present inventive concept illustrated in FIG. 13, the reliability of the semiconductor process may be improved by controlling the process results through process representing variables.

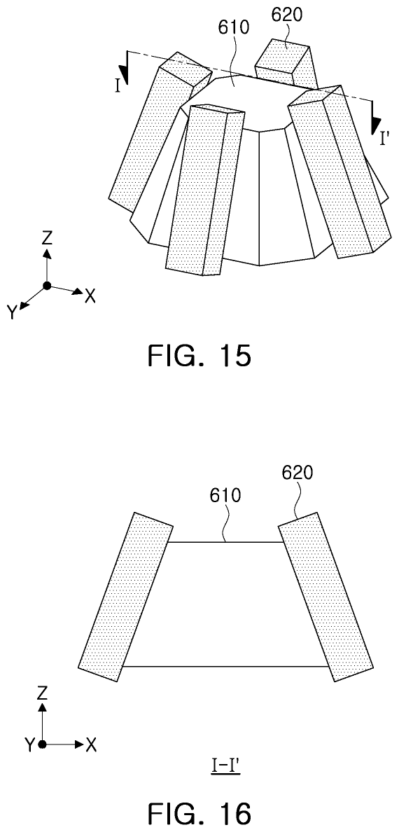

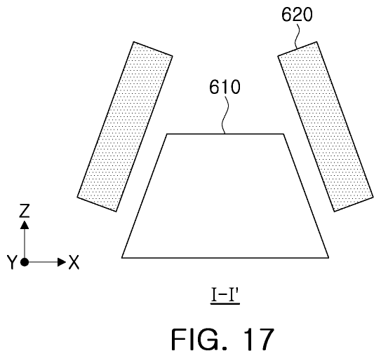

FIG. 15 is a diagram illustrating a rotating body and a plurality of OES apparatuses according to example embodiments. FIGS. 16 and 17 illustrate a cross-section in the I-I′ direction of FIG. 15, and are drawings illustrating the movement of the rotating body according to example embodiments.

Detailed embodiments of the semiconductor processing system may be the same as those previously described in FIGS. 1 to 14. For example, as in FIG. 3, the semiconductor processing system may include a semiconductor processing apparatus, an optical cable, a plurality of OES apparatuses, and the like.

First, referring to FIG. 15, in this example, the rotating body 610 may be in the shape of a polygonal pyramid with the top cut off. The bottom of the rotating body 610 may be a polygon or a regular polygon. The number of sides of the rotating body 610 may be equal to the number of the plurality of OES apparatuses 620 or may be greater than the number of the plurality of OES apparatuses 620. For example, the number of sides of the rotating body 610 may be a multiple of the number of the plurality of OES apparatuses 620.

In an example embodiment illustrated in FIG. 15, the rotating body 610 may have the shape of an octagonal pyramid. The bottom of the rotating body 610 is octagonal and may have eight sides. There may be four OES apparatuses 620, and the number of sides of the rotating body 610 may be twice the number of OES apparatuses 620. However, the present inventive concept may not be limited thereto.

One surface of each of the plurality of OES apparatuses 620 may be in contact with the rotating body 610. Each of the plurality of OES apparatuses 620 may generate OES data by receiving light emitted from the plasma through an optical cable connected to an area in contact with the rotating body 610. The plurality of OES apparatuses 620 in an example embodiment illustrated in FIG. 15 have a cuboid shape, and one surface of the cuboid may be in contact with the rotating body 610. However, the present inventive concept may not be limited thereto.

The rotating body 610 may move in a first direction (Z-axis direction in FIGS. 15 to 17) and be positioned at a first position and a second position. The rotating body 610 of FIGS. 15 and 16 is located at a first position and may come into contact with a plurality of OES apparatuses 620. The rotating body 610 of FIG. 17 is positioned at a second position as it moves in the first direction and may rotate based on the first direction. In an example embodiment illustrated in FIG. 17, the rotating body 610 may overlap a plurality of OES apparatuses 620 in the X-axis direction in the second position. However, the present inventive concept is not limited thereto, and the rotating body 610 may not overlap with the plurality of OES apparatuses 620 in the X-axis direction in the second position.

As the rotating body 610 rotates, each time the side of the rotating body 610 where one surface of each of the plurality of OES apparatuses 620 is in contact with the rotating body 610 changes, a plurality of OES apparatuses 620 may generate OES data. Hereinafter, the rotation of the rotating body 610 will be examined in detail.

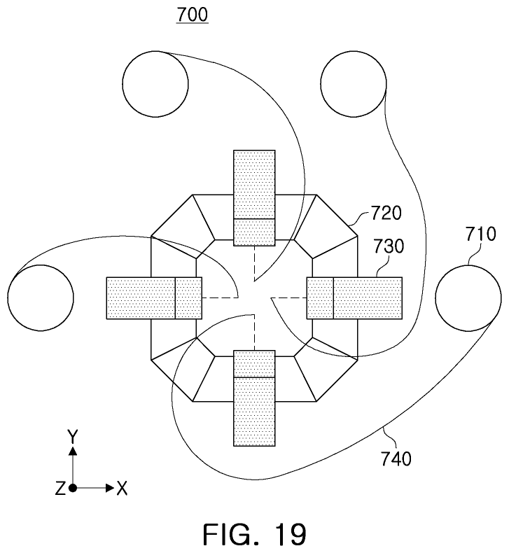

FIGS. 18 and 19 are diagrams schematically illustrating a semiconductor processing system according to example embodiments.

First, referring to FIGS. 18 and 19, a semiconductor processing system 700 may include a plurality of chambers 710, a rotating body 720, a plurality of optical cables 730, a plurality of OES apparatuses 740, and the like. The plurality of chambers 710 may each include a chamber body in which plasma is generated and a view port installed in the chamber body. Detailed embodiments of the semiconductor processing system may be the same as those previously described in FIGS. 1 to 14. For example, plurality of chambers 710 can correspond to plurality of chambers 212 of FIG. 4, plurality of optical cables 730 can correspond to optical cable 170 of FIG. 3, and plurality of OES apparatuses 740 can correspond to plurality of OES apparatuses 180 of FIG. 3.

Detailed embodiments of the rotating body 720 and the plurality of OES apparatuses 730 in FIGS. 18 and 19 may be the same as those previously described in FIGS. 15 to 17. For example, the rotating body 720 may be in the shape of a polygonal pyramid, such as an octagonal pyramid, and the number of sides of the rotating body 720 may be equal to the number of the plurality of OES apparatuses. The rotating body 720 may correspond to being located in the first position, and detailed embodiments of the first position may be the same as those described in FIGS. 15 and 16.

A first end of each of the plurality of optical cables 740 may be connected to the view port, and the second end may be connected to the rotating body 720. The second ends of the plurality of optical cables 740 may be connected to the side of the rotating body 720, and in detail, may be connected to the center of the side of the rotating body 720, respectively. At least one of the plurality of optical cables 740 may not be connected to an adjacent side of the rotating body 720. In an example embodiment illustrated in FIGS. 18 and 19, the plurality of optical cables 740 may not be connected to adjacent sides of the rotating body 720. For example, the side surface of at least one rotating body 720 may be included between the side surfaces where adjacent pairs of the plurality of optical cables 740 are connected.

The plurality of optical cables 740 may be inserted into the interior of the rotating body 720 in a first direction (Z-axis direction in FIGS. 18 and 19) from the upper surface of the rotating body 720. However, the present inventive concept may not be limited thereto.

One surface of each of the plurality of OES apparatuses 730 illustrated in FIGS. 18 and 19 may contact the side surface of the rotating body 720. Each of the plurality of OES apparatuses 730 may generate OES data by receiving light emitted from the plasma through each of the plurality of optical cables 740 connected to the side surface in contact with the rotating body 720.

FIG. 19 may illustrate that the rotating body 720 of FIG. 18 rotates by the rotation angle. The rotating body 720 may rotate based on the first direction. The rotation angle may be an angle formed by a pair of adjacent OES apparatuses among the plurality of OES apparatuses 730 in a second direction perpendicular to the first direction and parallel to the bottom of the rotating body 720. For example, in the distance and angle of a two-dimensional polar coordinate system with respect to the bottom of the rotating body 720, the second direction may correspond to the angular direction. The bottom of the rotating body 720 in an example embodiment illustrated in FIGS. 18 and 19 is octagonal, and the rotation angle may be a right angle. However, the present inventive concept may not be limited thereto.

As the rotating body 720 rotates, the side surface of the rotating body 720 where one surface of each of the plurality of OES apparatuses 730 is in contact with the rotating body 720 may be changed. As the rotating body 720 rotates, the plurality of OES apparatuses 730 that detect light emitted from the plurality of chambers 710 may be changed. For example, the combination of the plurality of chambers 710 and the plurality of OES apparatuses 730 may be changed.

The plurality of OES apparatuses 730 may be configured to generate the OES data at different orientations of the rotating body 720. For example, the plurality of OES apparatuses 730 may generate OES data whenever the side of the rotating body 720 in contact changes. The semiconductor processing system 700 may monitor the progress of the semiconductor process by correcting the generated OES data and calculating a process representing variable.

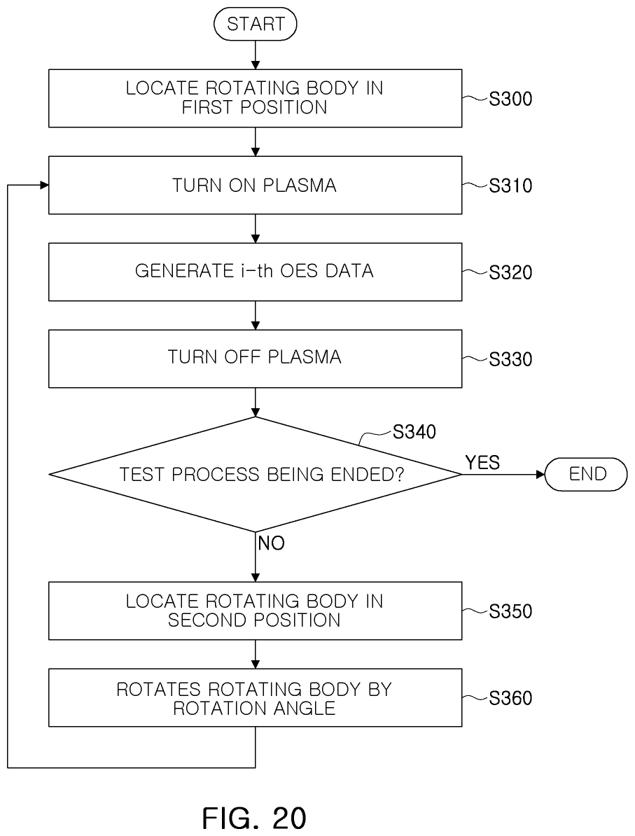

FIG. 20 is a flowchart illustrating the process of generating OES data during a test process performed before proceeding with the semiconductor process according to example embodiments.

The semiconductor processing system may calculate process conditions for each of a plurality of semiconductor processing apparatuses by performing a test process before the semiconductor process begins.

The semiconductor processing system may include a plurality of semiconductor processing apparatuses respectively including a chamber, an optical cable unit including a rotating body and a plurality of optical cables, a plurality of OES apparatuses, a processor, and the like. The processor may control a plurality of semiconductor processing apparatuses, an optical cable unit, and a plurality of OES apparatuses. Detailed embodiments of the semiconductor processing system may be the same as those previously described in FIGS. 1 to 19.

The processor may control the rotating body to be located in the first position (S300). Detailed embodiments of the first position may be to the same as those previously described in FIGS. 15 and 16. The processor may supply bias power to the first bias electrode and the second bias electrode of the semiconductor processing apparatuses to turn on the plasma (S310). For example, plasma may be generated in a plurality of chambers, and a semiconductor process using plasma may proceed.

A plurality of OES apparatuses may receive light emitted from the plasma through a view port and optical cables, detect the light emitted from the plasma, and generate OES data (S320). For example, the light emitted from the plasma generated in the first chamber is detected by the first OES apparatus, the light emitted from the plasma generated in the second chamber is detected by the second OES apparatus, and the light emitted from the plasma generated in the nth chamber may be detected by the nth OES apparatus.

After the generation of OES data is completed, the processor may turn off the plasma by blocking the bias power supplied to the first bias electrode and the second bias electrode of the semiconductor processing apparatuses (S330).

Afterwards, it may be determined whether the test process has ended (S340). The test process may end when OES data has been generated for all combinations of the plurality of chambers and the plurality of OES apparatuses. If the test process is not terminated (NO in S340), the generation of OES data may continue.

The processor controls the rotating body to be located in the second position (S350) and rotates the rotating body by the rotation angle (S360). Detailed embodiments of the second position may be the same as those previously described in FIGS. 17 to 19. The processor may control the rotating body to be located in the first position (S300) and turn on the plasma (S310).

A plurality of OES apparatuses may receive light emitted from the plasma through a view port and optical cables, detect the light emitted from the plasma, and generate OES data (S320). For example, light emitted from the plasma generated in the first chamber may be detected by the nth OES apparatus, light emitted from the plasma generated in the second chamber may be detected by the first OES apparatus, and the light emitted from the plasma generated in the nth chamber may be detected by the (n-1)th OES apparatus.

As the processor controls to repeat the above-described processes (S300 to S360), OES data may be generated in all combinations of a plurality of chambers and a plurality of OES apparatuses. The processor may calculate the OES data deviation model and process representing variable using the OES data, calculate the process model and target process representing variable, and calculate semiconductor process conditions. Multiple semiconductor processing apparatuses may be operated according to the calculated semiconductor processing conditions.

Thereafter, while the semiconductor process is in progress, the rotating body may be fixed in the second position without being rotated by the rotation angle. For example, OES data may be generated by a combination of one chamber and one OES apparatus (S300 to S330). The processor may correct the OES data using the OES data deviation model and calculate the process representing variable through the corrected OES data. Semiconductor process conditions may be controlled depending on whether the calculated process representing variable is within the normal range.

In some examples, the disclosed embodiments can include a method of manufacturing a semiconductor device using a semiconductor processing system. The method can include operating the semiconductor device, acquiring measurement data from a wafer that has been processed by the semiconductor process to obtain data. The method can additionally include rotating via a rotating body and acquiring measurement data, as described above in the examples of FIGS. 1-20. The method can additionally include providing calibration, and processing the wafers according to the calibration.

As set forth above, according to example embodiments, a process representing variable that may be matched to a semiconductor process result may be calculated by correcting deviations in data generated by an OES apparatus. Before a semiconductor process begins, semiconductor process conditions may be calculated using process representing variables. While the semiconductor process is in progress, the reliability of the semiconductor process may be improved and the yield may be improved by controlling the semiconductor process results to be constant using the calculated process representing variables.

While example embodiments have been illustrated and described above, it will be apparent to those skilled in the art that modifications and variations could be made without departing from the scope of the present inventive concept.

What is claimed is:

1. A semiconductor processing system comprising:
a plurality of chambers, each chamber including a chamber body having a space in which a semiconductor process using plasma is undertaken, and a view port installed in the chamber body;
an optical cable unit including a rotating body and a plurality of optical cables, a first end of each of the plurality of optical cables being connected to a corresponding view port and a second end being connected to the rotating body;
a plurality of Optical Emission Spectroscopy (OES) apparatuses configured to detect light emitted from plasma of a corresponding chamber and generate OES data; and
at least one processor configured to control the plurality of chambers, the optical cable unit, and the plurality of OES apparatuses,
wherein the plurality of OES apparatuses are configured to generate the OES data at different orientations of the rotating body, and
the at least one processor is configured to correct the OES data to generate corrected OES data, to calculate a process representing variable (PRV) using the corrected OES data, and to operate the plurality of chambers according to a semiconductor process condition calculated using the PRV.

2. The semiconductor processing system of claim 1, wherein the number of the plurality of OES apparatuses is the same as the number of the plurality of optical cables.

3. The semiconductor processing system of claim 2, wherein the number of the plurality of chambers is the same as the number of the plurality of OES apparatuses, and wherein each OES apparatus communicates optically with a corresponding chamber and generates the OES data from the corresponding chamber.

4. The semiconductor processing system of claim 1, wherein the plurality of OES apparatuses detect an optical spectrum of light emitted from the plasma of the corresponding chamber, measure intensity according to a wavelength of the light emitted from the plasma from the detected optical spectrum, and generate the OES data.

5. The semiconductor processing system of claim 4, wherein the OES data includes a plurality of peaks, and
the corrected OES data is obtained by correcting each of the plurality of peaks of at least one piece of the OES data for each of the plurality of chambers, with a reference wavelength and reference intensity.

6. The semiconductor processing system of claim 5, wherein the corrected OES data includes a first peak and a second peak, and
the process representing variable is a value obtained by dividing a first wavelength of the first peak by a second wavelength of the second peak.

7. The semiconductor processing system of claim 1, wherein the semiconductor process condition includes at least one of internal temperature and pressure of the plurality of chambers, passivation time and temperature for photoresist, and etching time and temperature for the photoresist.

8. A semiconductor processing system comprising:
a plurality of chambers, each chamber including a chamber body having a space in which a semiconductor process using plasma is undertaken, and a view port installed in the chamber body;
an optical cable unit including a rotating body and a plurality of optical cables, a first end of each of the plurality of optical cables being connected to a corresponding view port and a second end being connected to the rotating body;
a plurality of Optical Emission Spectroscopy (OES) apparatuses configured to detect light emitted from plasma of a corresponding chamber and generate OES data; and
at least one processor configured to control the plurality of chambers, the optical cable unit, and the plurality of OES apparatuses,
wherein one surface of each of the plurality of OES apparatuses is in optical communication with the rotating body, and each of the plurality of OES apparatuses is configured to receive light emitted from the plasma of the corresponding chamber through each of the optical cables connected to an area in contact with the rotating body, and generate the OES data at different orientations of the rotating body.

9. The semiconductor processing system of claim 8, wherein the number of the plurality of OES apparatuses, the number of the plurality of optical cables, and the number of the plurality of chambers are the same, and wherein each OES apparatus communicates optically with a corresponding chamber and generates the OES data from the corresponding chamber.

10. The semiconductor processing system of claim 8, wherein the rotating body has a polygonal pyramid shape.

11. The semiconductor processing system of claim 10, wherein the number of sides of the rotating body is a multiple of the number of the plurality of OES apparatuses.

12. The semiconductor processing system of claim 8, wherein the rotating body moves in the first direction and is located in a first position and a second position.

13. The semiconductor processing system of claim 12, wherein the rotating body is in contact with the plurality of OES apparatuses in the first position and rotates relative to the first direction in the second position.

14. The semiconductor processing system of claim 13, wherein the rotating body rotates by a rotation angle in the second position.

15. The semiconductor processing system of claim 14, wherein the rotation angle is an angle formed by a pair of adjacent OES apparatuses among the plurality of OES apparatuses in a second direction, perpendicular to the first direction and parallel to a bottom of the rotating body.

16. A semiconductor processing system comprising:
a plurality of chambers, each chamber including a chamber body having a space in which a semiconductor process using plasma is undertaken, and a view port installed in the chamber body;
an optical cable unit including a rotating body and a plurality of optical cables, a first end of each of the plurality of optical cables being connected to the view port and a second end being connected to the rotating body;
a plurality of Optical Emission Spectroscopy (OES) apparatuses configured to detect light emitted from plasma of a corresponding chamber and generate OES data;
a sensor acquiring measurement data from a wafer that has been processed by the semiconductor process; and
at least one processor controlling the plurality of chambers, the optical cable unit, the plurality of OES apparatuses, and the sensor,
wherein the plurality of OES apparatuses are configured to generate the OES data at different orientations of the rotating body,
wherein the plurality of OES apparatuses are configured to measure intensity according to wavelength from an optical spectrum of light emitted from the plasma and generate the OES data including a plurality of peaks,
wherein the at least one processor is configured to generate corrected OES data by correcting each of the plurality of peaks of at least one piece of the OES data for each of the plurality of chambers with a reference wavelength and reference intensity, create a process model using a process representing variable calculated using the corrected OES data, and calculate a target process representing variable from the process model, and
wherein the at least one processor is configured to operate the plurality of chambers according to a semiconductor process condition for each of the plurality of chambers calculated using the process representing variable, the process model, and the target process representing variable.

17. The semiconductor processing system of claim 16, wherein the corrected OES data includes a first peak and a second peak, and
the process representing variable is a value obtained by dividing a first wavelength of the first peak by a second wavelength of the second peak.

18. The semiconductor processing system of claim 16, wherein the measurement data includes a Critical Dimension (CD).

19. The semiconductor processing system of claim 16, wherein the process model includes an integrated process model and an individual process model,
wherein the integrated process model includes an integrated trend line of process representing variables of the plurality of chambers, and
the individual process model includes individual trend lines of a process representing variable for each of the plurality of chambers.

20. The semiconductor processing system of claim 16, wherein the semiconductor process condition includes at least one of internal temperature and pressure of the plurality of chambers, time and temperature of passivation for photoresist, and etching time and temperature for the photoresist.
